(19) United States
(12) Patent Application Publication
(10) Pub. No.: US 2013/0009028 A1
(43) Pub. Date: Jan. 10, 2013

(54) HARD DISK DRIVE BRACKET

(75) Inventor: YU-CHEN TING, Tu-Cheng (TW)

(73) Assignee: HON HAI PRECISION INDUSTRY CO., LTD., Tu-Cheng (TW)

(21) Appl. No.: 13/404,087

(22) Filed: Feb. 24, 2012

(30) Foreign Application Priority Data
Jul. 8, 2011 (TW) 100124358

(51) Int. Cl. H05K 7/14

(52) U.S. Cl. 248/314

(57) ABSTRACT

A bracket includes a bracket main body and a reinforce piece attached to the bracket main body. The bracket main body includes a base panel, a pair of side panels extending from opposite sides of the base panel, and a top panel connected to and located between the pair of side panels. The top panel includes a first plate extending substantially perpendicularly from an upper edge of a first side panel of the pair of side panels and a second plate extending substantially perpendicularly from an upper edge of a second side panel of the pair of side panels. The first plate and the second plate partially overlap with each other and fix to each other. The reinforce piece includes a first end secured to and located between the first plate and the second plate and a second end secured to an upper surface of the base panel.

### BACKGROUND

1. Technical Field

The present disclosure relates to brackets, and particularly to a bracket for hard disk drives.

2. Description of Related Art

With the advances in computer technology, people rely more on computers for both in personal life and in business. Thus, a great deal of data storage space for storing information is needed. The information may be loaded in hard disk drives. Generally, the hard disk drives are accommodated in a bracket that is mounted in a computer. The bracket includes a base plate, a pair of side plates extending perpendicularly from opposite sides of the base plate, a pair of top flanges extending perpendicularly from top edges of the pair of side plates, and a top plate secured to the pair of top flanges by screws. The hard disk drives vibrate during operation, which also vibrates the bracket. The top plate may be easily deformed due to the vibration.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded view of an embodiment of a bracket for hard disk drives, the bracket including a bracket main body and a reinforce piece.

FIG. 2 is a view of the bracket main body of FIG. 1 from a different aspect.

FIG. 3 is a schematic cross-sectional view of the bracket main body of FIG. 2.

FIG. 4 is an assembled view of the bracket of FIG. 1.

### DETAILED DESCRIPTION

The disclosure is illustrated by way of example and not by way of limitation. In the figures of the accompanying drawings in which like references indicate similar elements. It should be noted that references to “an” or “one” embodiment in this disclosure are not necessarily to the same embodiment, and such references mean at least one.

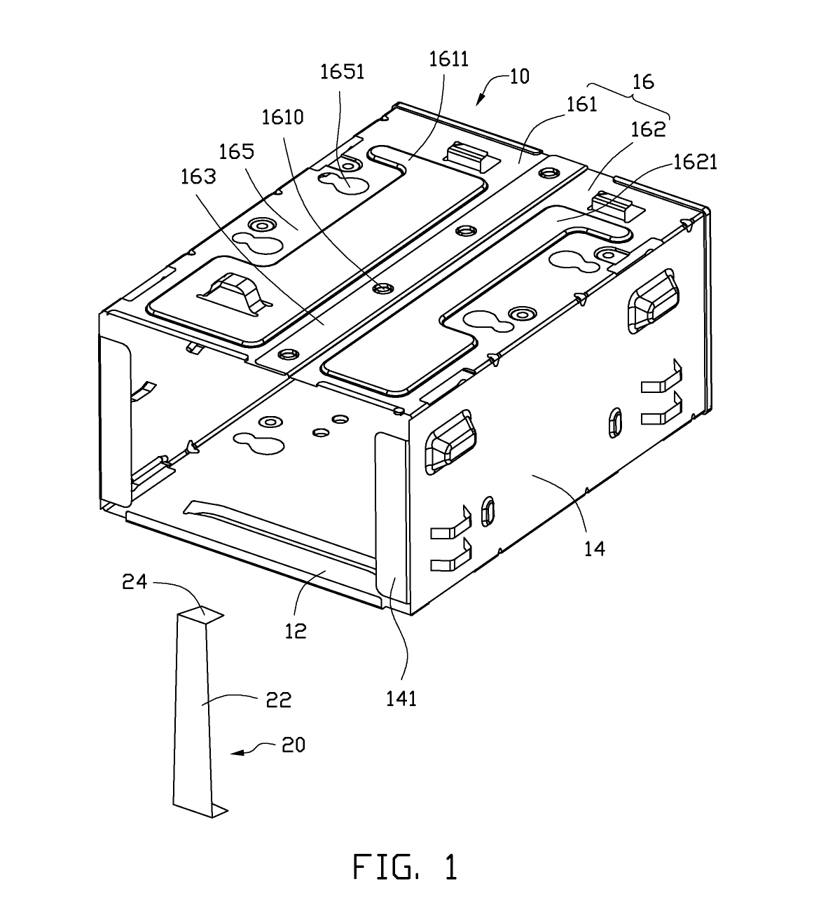

Referring to FIGS. 1 to 3, an embodiment of a bracket includes a bracket main body 10 and a reinforce piece 20. The bracket main body 10 includes a base panel 12, a pair of side panels 14 extending substantially perpendicularly from opposite sides of the base panel 12, and a top panel 16 connected to and located between the pair of side panels 14.

The top panel 16 includes a first plate 161 extending substantially perpendicularly from a top edge of a first side panel of the pair of side panels 14 and a second plate 162 extending substantially perpendicularly from a top edge of a second side panel of the pair of side panels 14. The second plate 162 includes a bent flange 163 abutting on the first plate 161. A plurality of securing holes (not labeled) is defined in the bent flange 163. A plurality of securing posts 1610 protrude from the first plate 161 and engages with the plurality of securing holes to secure the first plate 161 to the bent flange 163. A first protruding portion 1611 protrudes upwardly from the first plate 161. A second protruding portion 1621 protrudes upwardly from the second plate 162. A protruding height of the first protruding portion 1611 is substantially equal to that of the second protruding portion 1621. A shape of the first protruding portion 1611 is substantially similar to that of the second protruding portion 1621. An upper surface of each of the first protruding portion 1611 and the second protruding portion 1621 is substantially parallel to the base panel 12. The plurality of securing posts 1610 are located between the first protruding portion 1611 and the second protruding portion 1621 and lies on an imaginary line that is substantially parallel to the pair of side panels 14. A U-shaped gap portion 165 is defined in each of the first protruding portion 1611 and the second protruding portion 1621. A pair of calabash-shaped holes 1651 are defined in the U-shaped gap portion 165.

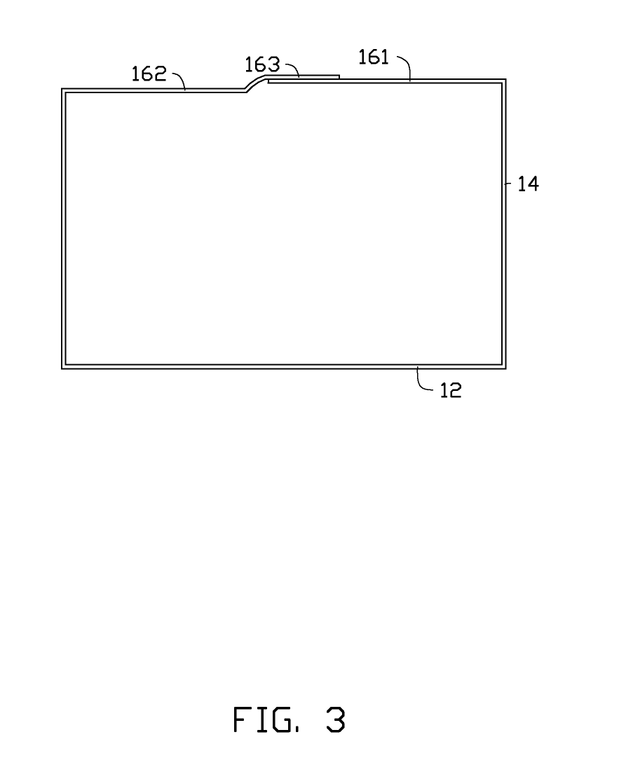

In one embodiment, the bracket main body 10 is integrally formed by bending a piece of metal plate (see FIG. 3). A width of the first plate 161 is substantially equal to that of the second plate 162. A length of each of the first plate 161 and the second plate 162 is substantially equal to that of each of the pair of side panels 14.

The reinforce piece 20 includes a main piece 22 and a pair of securing flanges 24 extending substantially perpendicularly from a pair of short edges of the main piece 22. The main piece 22 may have a substantially rectangular shape. A length of the main piece 22 is substantially equal to a distance between the top panel 16 and the base panel 12. A width of the main piece 22 is substantially equal to that of the bent flange 163.

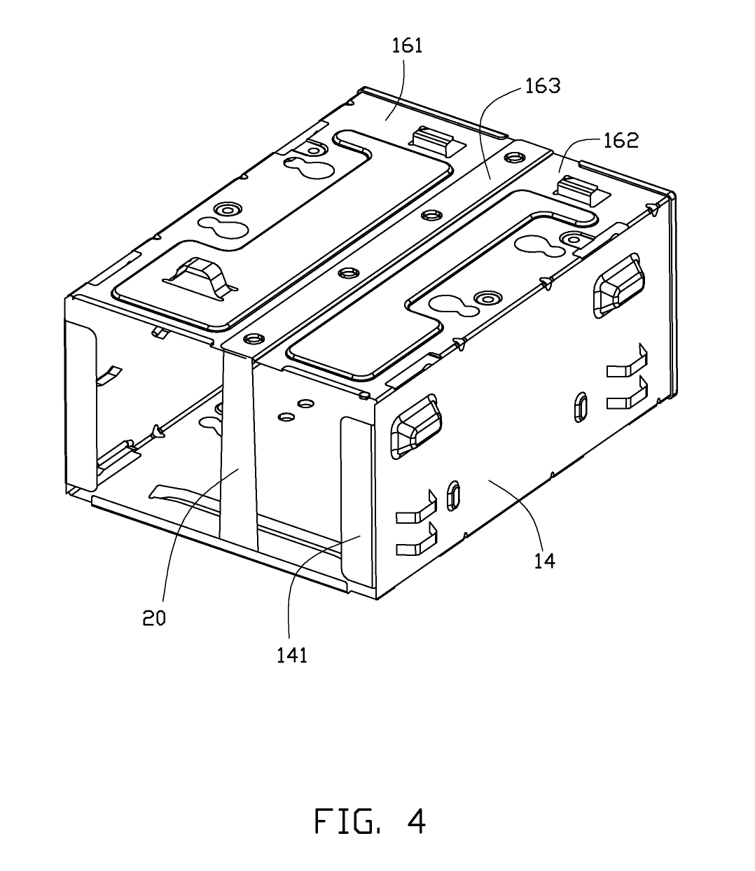

Referring to FIG. 4, in assembly, an upper flange of the pair of securing flanges 24 is secured to the first plate 161 by welding or other means and sandwiched between the first plate 161 and the bent flange 163. A lower flange of the pair of securing flanges 24 can be secured to an upper surface of the base panel 12 by welding or other means. The main piece 22 is substantially perpendicular to the base panel 12. The plurality of securing posts 1610 engage with the plurality of securing holes. The first plate 161 and the second plate 162 partially overlap with each other and fix to each other.

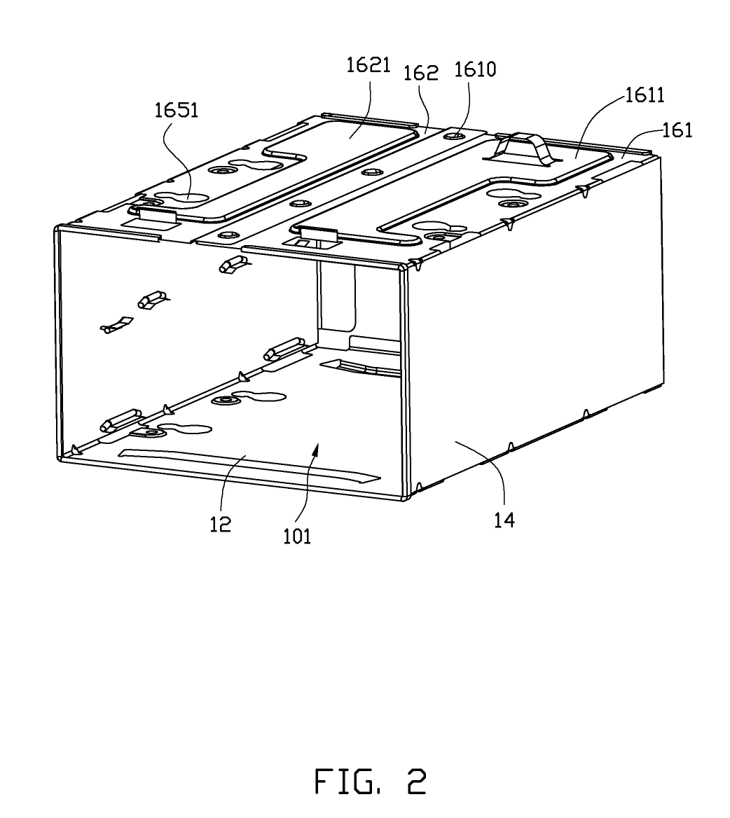

In one embodiment, the bracket main body 10 includes an entrance 101 located at a front side of the bracket main body 10 (see FIG. 2). Hard disk drives (not shown) can slide into the bracket main body 10 via the entrance 101. A pair of resisting flanges 141 extend substantially perpendicularly from rear edges of the pair of side panels 14 (see FIG. 4). The pair of resisting flanges 141 prevent the hard disk drives moving out from a rear side of the bracket main body 10. The reinforce piece 20 is located at the rear side of the bracket main body 10 and lies in the same plane as the pair of resisting flanges 141. A rear portion of each of the hard disk drives generates greater vibration than any other portion of each of the hard disk drives in use. The reinforce piece 20 can improve the shock-resisting ability of the bracket main body 10 and decrease the vibration of the bracket main body 10.

While the present disclosure has been illustrated by the description in this embodiment, and while the embodiment has been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

What is claimed is:

1. A bracket comprising:
a bracket main body comprising a base panel, a pair of side panels extending from opposite sides of the base panel, and a top panel connected between the pair of side panels and opposite to the base panel; the top panel comprising a first plate extending substantially perpendicularly from an upper edge of a first side panel of the pair of side panels, and a second plate extending substantially perpendicularly from an upper edge of a second side panel of the pair of side panels; wherein the first plate and the second plate partially overlap with each other and fix to each other; and
a reinforce piece comprising a first end secured between the first plate and the second plate, and a second end secured to an upper surface of the base panel.

2. The bracket of claim 1, wherein the reinforce piece comprises a main piece, an upper securing flange extending substantially perpendicularly from an upper edge of the main piece, and a lower securing flange extending substantially perpendicularly from a lower edge of the main piece; the upper securing flange is secured between the first plate and the second plate, the lower securing flange is secured to the base panel.

3. The bracket of claim 2, wherein the bracket main body comprises an entrance located at a front side of the bracket main body, the reinforce piece is located at a rear side of the bracket main body.

4. The bracket of claim 3, wherein the main piece is substantially perpendicularly to the base panel, the pair of side panels, and the top panel.

5. The bracket of claim 2, wherein the second plate comprises a bent flange abutting on the first plate, the upper securing flange is secured between the first plate and the bent flange.

6. The bracket of claim 5, wherein the main piece is substantially rectangular shaped, a length of the main piece is substantially equal to a distance between the base panel and the top panel, and a width of the main piece is substantially equal to a width of the bent flange.

7. The bracket of claim 5, wherein the first plate comprises a first protruding portion, the second plate comprises a second protruding portion, and the bent flange is located between the first protruding portion and the second protruding portion.

8. The bracket of claim 7, wherein a shape of the first protruding portion is substantially similar to a shape of the second protruding portion, and an upper surface of each of the first protruding portion and the second protruding portion is substantially parallel to the base panel.

9. The bracket of claim 8, wherein a U-shaped gap portion is defined in each of the first protruding portion and the second protruding portion, and a pair of calabash-shaped holes are defined in the U-shaped gap portion.

10. The bracket of claim 1, wherein the bracket main body is integrally formed by bending a piece of metal plate.

11. A bracket comprising:
a bracket main body comprising a base panel, a pair of side panels extending from opposite sides of the base panel, a first plate extending substantially perpendicularly from an upper edge of a first side panel of the pair of side panels, and a second plate extending substantially perpendicularly from an upper edge of a second side panel of the pair of side panels; wherein the first plate and the second plate partially overlap with each other and fix to each other; and
a reinforce piece comprising a main piece and a pair of securing flanges extending substantially perpendicularly from opposite edges of the main piece, one of the pair of securing flanges being secured between the first plate and the second plate, and another one of the pair of securing flanges being secured to an upper surface of the base panel.

12. The bracket of claim 11, wherein the bracket main body comprises an entrance located at a front side of the bracket main body, the reinforce piece is located at a rear side of the bracket main body.

13. The bracket of claim 11, wherein the main piece is substantially perpendicularly to the base panel and the pair of side panels.

14. The bracket of claim 11, wherein the second plate comprises a bent flange abutting on the first plate, one of the pair of securing flanges is secured between the first plate and the bent flange.

15. The bracket of claim 14, wherein the main piece is substantially rectangular shaped, a length of the main piece is substantially equal to a distance between the base panel and the first plate, and a width of the main piece is substantially equal to a width of the bent flange.

16. The bracket of claim 14, wherein the first plate comprises a first protruding portion, the second plate comprises a second protruding portion, and the bent flange is located between the first protruding portion and the second protruding portion.

17. The bracket of claim 16, wherein a shape of the first protruding portion is substantially similar to a shape of the second protruding portion, and an upper surface of each of the first protruding portion and the second protruding portion is substantially parallel to the base panel.

18. The bracket of claim 17, wherein a U-shaped gap portion is defined in each of the first protruding portion and the second protruding portion, and a pair of calabash-shaped holes are defined in the U-shaped gap portion.

19. The bracket of claim 11, wherein a width of the first plate is substantially equal to a width of the second plate, a length of each of the first plate and the second plate is substantially equal to a width of each of the pair of side panels.

20. The bracket of claim 11, wherein the bracket main body is integrally formed by bending a piece of metal plate.
